(19) United States
(12) Patent Application Publication
(10) Pub. No.: US 2014/0073224 A1
(43) Pub. Date: Mar. 13, 2014

(54) METHOD FOR PROCESSING EDGE SURFACE AND EDGE SURFACE PROCESSING APPARATUS

(71) Applicant: KABUSHIKI KAISHA TOSHIBA, Tokyo (JP)

(72) Inventor: Daisuke YAMASHITA, Ishikawa (JP)

(73) Assignee: KABUSHIKI KAISHA TOSHIBA, Tokyo (JP)

(21) Appl. No.: 13/776,491

(22) Filed: Feb. 25, 2013

(30) Foreign Application Priority Data
Sep. 7, 2012 (JP) P2012-197939

(51) Int. Cl. H01L 21/67; B24B 7/22

(52) U.S. Cl. CPC H01L 21/67115; H01L 21/67092; B24B 7/228
USPC 451/29; 219/121.68; 451/69

(57) ABSTRACT

An aspect of the present embodiment, there is provided a method of fabricating a semiconductor device, including grinding a second surface of a wafer, the second surface opposite to a first surface of the wafer being stuck with a surface protection material, forming a protective film on the first surface, irradiating a portion including an outside edge of the wafer with laser light to remove the portion including the outside edge in a state that the wafer is rotating and an irradiation position of the laser light is approaching to a rotation axis of the wafer, an absorption ratio of the wafer to the laser light being higher than an absorption ratio of the surface protection material to the laser light, and removing the protective film.

### CROSS REFERENCE TO RELATED APPLICATION

This application is based upon and claims the benefit of priority from prior Japanese Patent Application No. 2012-197939, filed on Sep. 7, 2012, the entire contents of which are incorporated herein by reference.

### FIELD

Exemplary embodiments described herein generally relate to a method for processing an edge surface and an edge surface processing apparatus.

### BACKGROUND

A process of a wafer to be thinned can be used in processing steps of fabricating semiconductor devices. The wafer is processed to be thinned in order to fabricate multi-layer chips and thinning-type chips, for example, in system LSIs and memories such as dynamic random access memories, NAND/NOR-type flash memories, magneto resistive random access memories and ferroelectric random access memories.

Further, the wafer is processed to be thinned in order to lower conductive loss in discrete semiconductor devices, on-resistance in power MOSFETs, and on-voltage in insulated gate bipolar transistors, for example.

In a thinning process, a back surface of the wafer is grinded. Edge trimming is performed to an edge of the wafer in front or behind in order to suppress generation of an edge crack in subsequent processes. Conventionally, edge trimming is performed to remove the edge of the wafer by a blade.

As timing on performing the edge trimming, two cases is considered, one is before sticking a surface protection material on the wafer and the other is after sticking a surface protection material on the wafer. The surface protection material protects a front surface of the wafer in the thinning process. A glass wafer support system, for example, can be utilized. When edge trimming is performed before sticking the surface protection material, debris D generated by the edge trimming are sandwiched between the wafer and the surface protection material, so that the wafer may be broken in the thinning process.

On the other hand, when edge trimming is performed after sticking the surface protection material, breakage originated by the debris D described above can be suppressed. However, there arises a difficult problem in the process that a leading edge of the blade processes only the wafer to precisely control a stopping position not to contact with the surface protection material. In other words, when the leading edge of the blade is shortage to a precise position, an edge of the wafer is leaved. On the contrary, when the leading edge of the blade is over to the precise position, the leading edge of the blade can be contacted to the surface protection material.

### BRIEF DESCRIPTION OF THE DRAWINGS

FIG. 1 is a schematic plane view showing an edge surface processing apparatus according to a first embodiment;

FIG. 2 is a flowchart showing a method for processing an edge surface according to the first embodiment;

FIGS. 3A-3B are a cross-sectional view and a plane view, respectively, showing the method for processing the edge surface according to the first embodiment;

FIGS. 4A-4D are cross-sectional views showing the method for processing the edge surface according to the first embodiment;

FIG. 5 is a schematic plane view showing an edge surface processing apparatus according to a second embodiment;

FIG. 6 is a flowchart showing a method for processing an edge surface according to the second embodiment;

FIGS. 7A-7D are cross-sectional views showing the method for processing the edge surface according to the second embodiment;

FIGS. 8A-8B are SEM photographs showing a processed surface by a laser ablation method and a processed surface by a blade method, respectively.

### DETAILED DESCRIPTION

An aspect of the present embodiment, there is provided a method of fabricating a semiconductor device, including grinding a second surface of a wafer, the second surface opposite to a first surface of the wafer being stuck with a surface protection material, forming a protective film on the first surface, irradiating a portion including an outside edge of the wafer with laser light to remove the portion including the outside edge in a state that the wafer is rotating and an irradiation position of the laser light is approaching to a rotation axis of the wafer, an absorption ratio of the wafer to the laser light being higher than an absorption ratio of the surface protection material to the laser light, and removing the protective film.

Another aspect of the present embodiment, there is provided a method of fabricating a semiconductor device, including an laser irradiation unit configured to irradiate a portion including an outside edge of a plate member with a laser light, a surface protection material being stuck on a first surface of the plate member, an absorption ratio of the plate member to the laser light being higher than an absorption ratio of the surface protection material to the laser light, and an alignment unit configured to relatively move an irradiation position of the laser light along an outside edge.

### First Embodiment

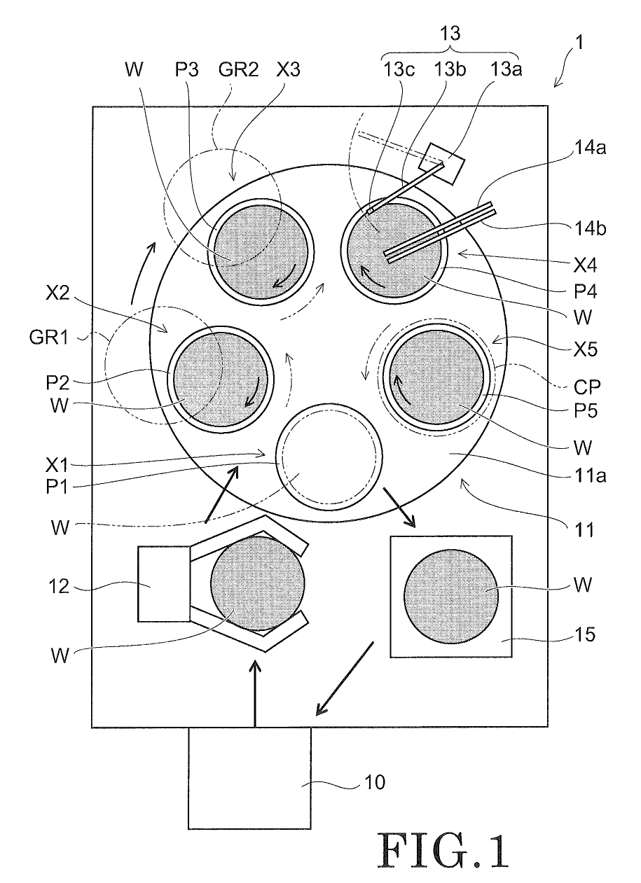

Embodiments will be described below in detail with reference to the drawings mentioned above. First, an edge surface processing apparatus according to a first embodiment are explained with reference to FIGS. 1-4. FIG. 1 is a schematic plane view showing the edge surface processing apparatus according to the first embodiment. The edge surface processing apparatus in this embodiment processes an edge surface of a wafer.

As shown in FIG. 1, a rotation stage 11 is provided in an edge surface processing apparatus 1 according to the first embodiment. A top plate 11a is provided on the rotation stage 11 and five platforms P1-P5 are provided on the top plate 11a. The rotation stage 11 is configured to rotate the platforms P1-P5 round the top plate 11a by rotating the top plate 11a on its axis. Each of the platforms P1-P5 is disposed on each of sites X1-X5 in the edge surface processing apparatus 1. Each wafer W is mounted on each of the platforms P1-P5. Each of the platforms P1-P5 is a rotation unit which is configured to rotate the wafer W on its axis as a rotation axis.

A transfer unit 12 is set up in the edge surface processing apparatus 1. The transfer unit 12 is configured to unload the wafer W from a carrier 10 and transfer to each of the platforms P1-P5 located at each of sites X1-X5 to mount the wafer W on each of the site X1-X5. Furthermore, the transfer unit 12 configured to unload from each of the platforms P1-P5 located at each of the sites X1-X5 and is configured to transfer the wafer W to the carrier 10.

A grind stone GR1 for rough grinding is provided at an upper side of the site X2. The grind stone GR1 is located at a position which passes a center axis of the wafer, where an outer edge of the wafer is located at the site X2. Granularity of the grind stone GR1 is set to be nearly #300, for example. The grind stone GR1 can be movable to upper and lower, and is configured to contact to the wafer W located at the site X2 when the grind stone GR1 is located at the low end in the transfer range. Furthermore, the grind stone GR1 is configured to reversely rotate to a rotation direction of the wafer W due to the rotation of the platform.

A grind stone GR2 for fine grinding is provided at an upper side of the site X3. The grind stone GR2 is located at a position which passes a center axis of the wafer, where an outer edge of the wafer is located at the site X3. A grinding surface of the grind stone GR2 is finer than that of the grind stone GR1 and granularity of the grind stone GR2 is set to be nearly #2,000, for example. The grind stone GR2 can be movable upper and lower, and is configured to contact to the wafer W located at the site X3 when the grind stone GR2 is located at the low end in the transfer range. Furthermore, the grind stone GR2 is configured to reversely rotate to a rotation direction of the wafer W due to the rotation of the platform.

A laser irradiation unit 13 is located near the site X4. The laser irradiation unit 13 includes a light source section 13a oscillating laser light L, an optical pass section 13b guiding the laser light L, and an outlet portion 13c exiting the laser light L in a lower direction. The light source section 13a is fixed in the edge surface processing apparatus 1, and oscillates the laser light L with a wavelength of 300-2,000 nm, for example, 366 nm, 532 nm, or 1,064 nm. The laser light L with a wavelength in such the range is absorbed by silicon, however, is hard to be absorbed by silicon oxide.

The optical pass section 13b can be movably connected to the light source section 13a. In such a manner, the optical pass section 13b can arbitrarily select a position of the outlet portion 13c in a prescribed range. The optical pass section 13b is linear, for example, the one end portion is movably connected to the light source section 13a and the outlet portion 13c is attached at the other portion. The outlet portion 13c is configured to move along an orbit with arc by rotationally moving of the optical pass section 13b, so that an exiting region of the laser light L is moved in a radial direction of the platform located at the site X4. In other words, the optical pass section 13b has a function of a moving unit which is configured to moving an irradiation area of the laser light L in the radial direction of the wafer W. On the other hand, each of the platforms P1-P5 selects an angle to the rotation stage 11 by rotating the wafer W round its axis. In such a manner, each of the platforms P1-P5 relatively move the irradiation area of the laser light L along the circumferential direction of the wafer W. A function of an alignment unit, which relatively moves the irradiation area of the laser light L along an outside edge of the wafer W, is constituted with the platforms P1-P5 as rotation sections and the optical pass section 13b as a moving section.

Furthermore, a solution tube 14a and a pure water tube 14b are provided at an upper side of the site X4. The solution tube 14a discharges a solution to form a protective film 56 and the pure water tube 14b discharges pure water. The solution tube 14a and the pure water tube 14b discharge the solution and pure water, respectively, to a rotation axis of the wafer W located on the site X4 or the near region. The solution tube 14a has a function of a forming unit for forming a film to form a protective film 56 on a back surface of the wafer and the water tube 14b has a function of a removing unit for removing a film to remove the protective film 56 from the wafer W.

A pad CP for CMP (Chemical Mechanical Polishing) is provided above the site X5. The pad CP can be movable to upper and lower and is contacted to the wafer W located on the site X5 when the pad CP is positioned at a lower end of the moving region. Further, the pad CP reversely rotates round its axis in the rotation direction of the wafer around its axis due to the rotation of the platform.

A cleaning unit 15, which cleans by ultrasonic cleaning or the like using pure water, is provided in the edge surface processing apparatus 1. The wafer W is attached and removed to the cleaning unit 15 by the transfer unit 12.

Next, action of the edge surface processing apparatus constituted as described above according to the first embodiment, in other words, a method for processing an edge surface is explained.

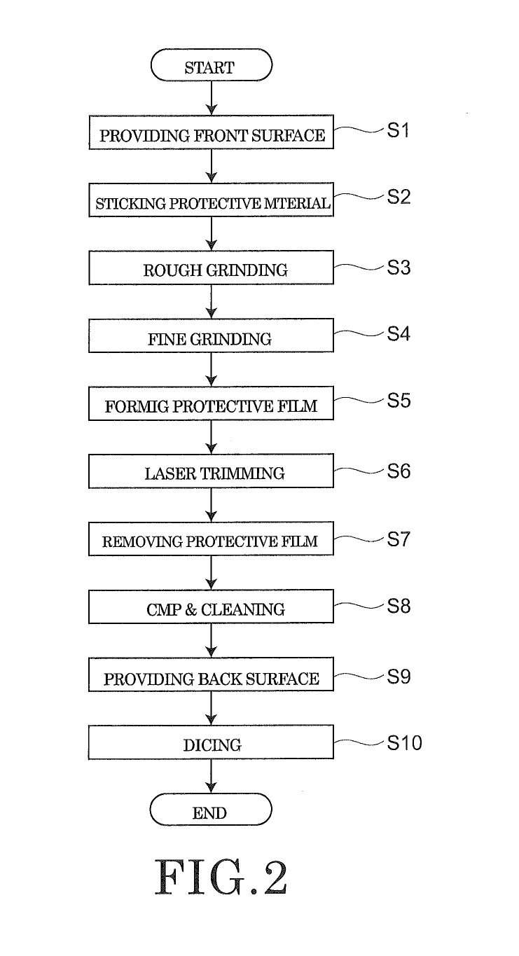

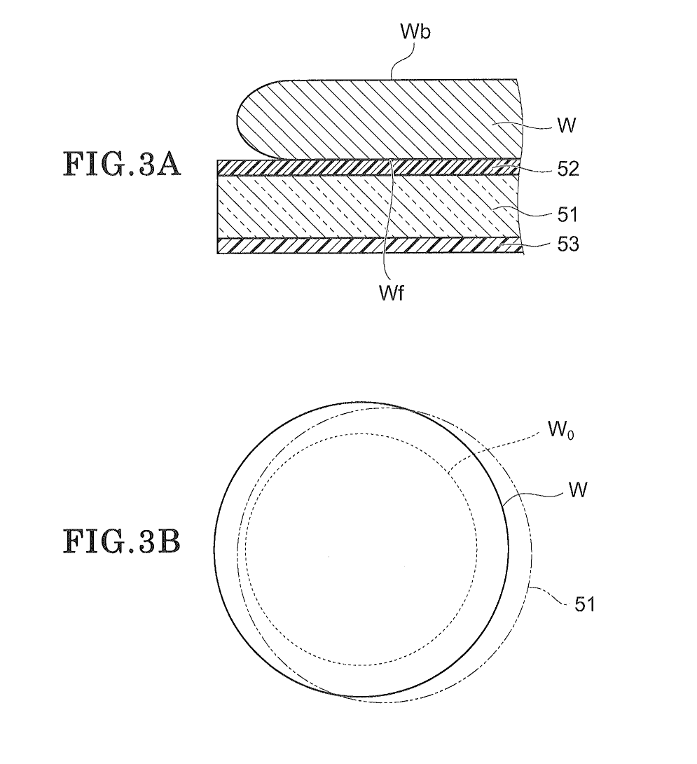

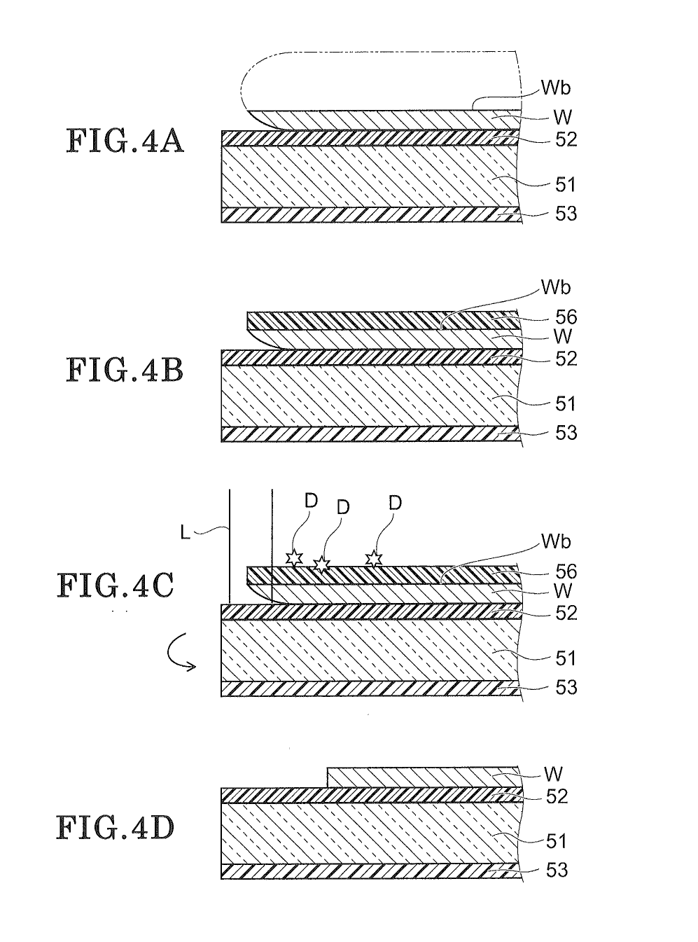

FIG. 2 is a flowchart showing a method for processing an edge surface according to the first embodiment. FIGS. 3A-3B are a cross-sectional view and a plane view, respectively, showing the method for processing the edge surface according to the first embodiment. FIGS. 4A-4D are cross-sectional views showing the method for processing the edge surface according to the first embodiment.

A method for processing the edge surface according to the first embodiment is a method for processing an edge surface of semiconductor wafer W, and is included in a part of a method for fabricating a semiconductor device. The method for processing the edge surface of the wafer W is described with processing steps before and after mentioned below. Namely, the method for processing the edge surface is described in the method for fabricating the semiconductor device. On the other hand, other than the method for processing the edge surface in the method for fabricating the semiconductor device is simply described.

As shown at step S1 in FIG. 2, a surface structure of an impurity diffusion layer, an insulator, a surface electrode and the like are formed on a surface W_{f} of a wafer W composed of silicon (reference to FIG. 3A) at Step S1.

As shown at step S2 in FIG. 2 and FIG. 3A, a surface protection material is stuck on the surface W_{f} of the wafer W at Step S2. In this step, an end portion of the wafer W has a round shape. The surface protection material is Glass Wafer Support System, for example (GWSS), and includes a glass substrate with a disk shape composed of quartz glass. The glass substrate 51 is stuck to the surface W_{f} of the wafer W via an adhesive 52. A BSG (Back Side Grinding) tape is attached to an opposed surface to the surface of glass substrate 51 stuck with the wafer W. In this step, a back surface W_{b} of the wafer W is exposed to be not attached by any material.

As shown in FIG. 3B, a position of the glass substrate 51 may shift to the wafer W due to an error of the attachment in this step. In this case, from view point of a stacked direction with the wafer W and the glass substrate 51, a part of an end portion of the wafer W is protruded out of the glass substrate 51 to generate a crack in the protruded portion during subsequent processes. Therefore, the wafer W is carried out to be edge trimming to shrink a diameter of the wafer till a shrinkage size W₀ as shown by broken lines in the FIG. 3B, as described after. In such a manner, the wafer W is installed inside the glass substrate 51 from the viewpoint of the stacked direction so that generation of crack can be prevented. When diameters of the glass substrate 51 and the wafer W before the edge trimming are 200 mm long and an error size in sticking is 0.3 mm long in maximum, for example, an edge portion of the wafer W is removed in width of 0.5 mm by the edge trimming. In such a manner, an outside edge of the wafer W is positioned at least a width of 2 mm inner than an outside edge of the glass substrate 51. In this case, the diameter of the wafer W after the edge trimming is a width of 199 mm. For easily understanding, the error in the sticking is described to be overstated in FIG. 3.

As shown in FIG. 1, the glass substrate 51 and the wafer W stuck with the BSG tape 53, which is simply called the wafer W hereinafter, are provided in the edge surface processing apparatus 1 by using carrier 10. A transfer unit 12 in the edge surface processing apparatus 1 unloads the wafer W from the carrier 10 and transfers the wafer W to the site X1. The wafer W is mounted on one of the platforms located at the site X1. The platform P1 is positioned in the site X1. The wafer W is stuck on the platform P1 at a side of the surface R_{f}, in other words, as a state that a side of the BSG tape directs to a lower portion. Therefore, a back surface W_{b} of the wafer W in a state as exposed is directed to an upper portion.

As shown at Step S3 in FIG. 2, rough grinding is carried out to the wafer W. As shown in FIG. 1, the rotation stage 11 rotates the top plate 11a with a predetermined angle so that the platform P1 is located on the site X2. The platform P1 rotates the wafer W clockwise from viewpoint of an upper portion, for example. On the other hand, the grind stone GR1 for rough grinding comes downwards to contact to the back surface of the wafer W, while the grind stone GR1 is reversely rotated in the rotation direction of own axis of the wafer W, counterclockwise from viewpoint of an upper portion. In such a manner, the back surface W_{b} of the wafer W is performed to be roughly grinded.

As shown at Step S4 in FIG. 2, finely grinding is carried out to the wafer W. As shown in FIG. 1, the rotation stage 11 rotates the top plate 11a with a predetermined angle so that the platform P1 is located on the site X3. The platform P1 rotates the wafer W clockwise from viewpoint of an upper portion, for example. On the other hand, the grind stone GR2 for fine grinding comes downwards to contact to the back surface W_{b} of the wafer W, while the grind stone GR1 is reversely rotated in the rotation direction of own axis of the wafer W, counterclockwise from viewpoint of the upper portion. In such a manner, the back surface W_{b} of the wafer W is performed to be finely grinded. As a result, as shown in FIG. 4A, a portion in a back surface side of the wafer is removed so that the wafer is thinned to a prescribed thickness.

As shown at Step S5 in FIG. 2, a protective film 56 is provided on the wafer W. As shown in FIG. 1, the rotation stage 11 rotates the top plate 11a a predetermined angle so that the platform P1 is located on the site X4. The platform P1 rotates the wafer. In such a state, a solution tube 14a discharges a solution. In such a manner, as shown in FIG. 4B, the protective film 56 is provided on the back surface W_{b} of the wafer W with water solubility by spin coating.

As shown at Step S6 in FIG. 2, laser trimming is carried out to the wafer W. As shown in FIG. 1 and FIG. 4C, the platform P1 rotates the wafer W. On the other hand, the optical pass section 13b of the laser irradiation unit 13 rotationally moves to the light source section 13a to position the outlet portion 13c above a portion including an outside edge of the wafer W. In such a state, the light source section 13a oscillates laser light L which is set to have an absorption ratio of the wafer W to the laser light L being higher than an absorption ratio of the glass substrate 51 to the laser light L. The light source section 13a oscillates laser light L with a wave length of 200-300 nm, 366 nm, 532 nm or 1,064 nm, for example. Laser light L in the range of such wavelengths is absorbed by the wafer W composed of silicon, however is hardly absorbed by the glass substrate 51. Furthermore, the BSG tape is also selected not to be damaged by laser light L in the range of such wavelengths such as fusion, sublimation, burnout or the like.

As shown in FIG. 4C, a portion irradiated with laser light L in the wafer W is heated to be ablated. A part of the ablated silicon gas solidified again, however, most of the ablated silicon gas is exhausted out of the edge surface processing apparatus 1. In such a manner, a portion irradiated with laser light L in the wafer W is removed. On the other hand, laser light L is hardly absorbed by the glass substrate 51, as a result, the glass substrate 51 hardly heated to not to be damaged. Furthermore, the platform P1 rotates the wafer W, accordingly, an irradiated area of laser light L is moved along the outside edge of the wafer W to remove a portion including the outside edge. The optical pass section 13b rotationally moves in synchronization with the wafer W. Therefore, an irradiation position of the laser light L is swept to be approached to the rotation axis of the wafer W. In such a manner, an edge portion of the wafer W is spirally removed. Further, the sweep is finished when the diameter of the wafer W is reached at a target value. Consequently, trimming with an arbitral width can be performed to the wafer W.

In such a process, the ablated silicon is solidified again to generate debris D. However, as the back surface W_{b} of the wafer W is covered with the protective film 56, the debris D is attached to the protective film 56 not to attach to the back surface W_{b} of the wafer W.

As shown at step 7 in FIG. 2, the protective film 56 is removed. Namely, in a state that the platform P1 retains rotation of the wafer W, a pure water tube 14b discharges pure water, for example, DIW (Deionized Water). In such a way, as shown in FIG. 4D, the protective film 56 with water solubility is dissolved to be removed. In such the process, the debris D attached on the protective film 56 is also removed with the protective film 56.

As shown at step S8 in FIG. 2, a CMP process is carried out to the wafer W. In other words, as shown in FIG. 1, the rotation stage 11 rotates the top plate 11a for a prescribed angle to position the platform P1 at the site X5. Further, the platform P1 rotates the wafer W with its own axis from the top view. On the other hand, a pad CP for CMP comes down to contact with the wafer W, in a state where the pad CP rotates counterclockwise with its own axis, for example, from the top view. In such a manner, the CMP process is carried out to the wafer W.

As shown in FIG. 1, the rotation stage 11 rotates the top plate 11a for a prescribed angle to position the platform P1 at the site X1. Further, the transfer unit 12 unfixes the wafer W from the platform P1 to transfer to the cleaning unit 15. The cleaning unit 15 performs a cleaning process with pure water to the wafer W. The transfer unit 12 transfers the wafer W from the cleaning unit 15 to the carrier 10 and insert the wafer W in the carrier 10. The carrier 10 is leaved from the edge surface processing apparatus 1. In such a manner, the wafer W is removed from the edge surface processing apparatus 1. Here, the processing steps mentioned above are simultaneously carried out in the sites X1-X5.

As shown at Step S9 in FIG. 2, a back surface structure is form on the back surface W_{b} of the wafer W. An ion-implantation process is carried out into the back surface W_{b} of the wafer W to form an impurity diffusion layer (not shown). Further, a back surface electrode (not shown) is formed on the back surface W_{b}. In the process, the glass substrate 51 protects the surface W_{f} of the wafer W.

The adhesive 52 is dissolved by chemical solution, for example, to remove the glass substrate 51 from the wafer W. As shown at Step S10 in FIG. 2, the wafer W is diced to be separated to a plurality of chips. In such a manner, a plurality of semiconductor devices can be fabricated.

Effects of the first embodiment are explained below. As shown at Step S6 in FIG. 2, the laser irradiation unit 13 irradiates the portion including the outside edge of the wafer W with laser light L which is had a higher absorption ratio by the wafer W than a absorption ratio by the glass substrate 51 to be able to ablate the portion including the outside edge of the wafer W without damage to the glass substrate 51 in the first embodiment. As a result, edge trimming can be carried out in a state that the glass substrate 51 is remained, so that the wafer W can be installed in the glass substrate 51 from a view point of stacked direction with the wafer W and glass substrate 51. In such a manner generation of cracks at the edge of the wafer W can be prevented in subsequent processes.

Further, laser trimming is carried out (step S6) after the glass substrate 51 as a surface protection material is stuck on the surface W_{f} of the wafer W (step S2) in the first embodiment. The debris D generated by laser trimming are not sandwiched between the wafer W and the glass substrate 51 by using the process described above. Consequently, the wafer W is not cracked due to the debris D in the subsequent process.

Further, rough grinding (step S3) and fine grinding (step S4) are performed to thin the wafer W, successively laser trimming is carried out in the first embodiment. Therefore, a thickness of the wafer W removed by laser trimming is thinner so that efficiency of laser trimming is higher. In other words, an output of laser light L is not necessary to be heightened in excess so that a portion positioned at irradiation of laser light L in the wafer W can be ablated.

In the first embodiment, the protective film 56 is formed on the back surface W_{b} of the wafer W (step S5), before laser trimming (step S6). Further protective film 56 (step S7) is removed after laser trimming (step S6). In such a manner, the debris D generated by laser trimming is attached on the protective film 56 to remove the debris D with the protective film 56. As a result, the debris D can be effectively removed.

Moreover, the optical pass section 13b of the laser irradiation unit 13 approaches the irradiation area of the laser light L to the rotation axis of the wafer W with relating to the rotation of the wafer W by the platform P1-P5 in the first embodiment. In such a manner, the irradiation area of the laser light L can be spirally moved to the wafer W. Accordingly, laser irradiation can be continuously performed so that edge trimming of the wafer W can be uniformly and effectively carried out.

Further, the sites X1-X5 are set in the edge surface processing apparatus 1, the platforms P1-P5 are set and top plate 11a is rotated in the first embodiment. In such a manner, each of the platforms P1-P5 is serially set at each of the sites X1-X5, attachment replacement and re-movement, rough grinding, fine grinding, laser trimming and CMP of the wafer W can be simultaneously performed in parallel. Consequently, decrease of throughput of the wafer W by laser trimming can be suppressed.

Further, the laser irradiation unit 13, the solution tube 14a and pure water tube 14b are set in the BSG apparatus which perform rough grinding and fine grinding in the first embodiment. In such a manner, edge surface processing apparatus 1 is realized. In other words, mechanisms of forming the protective film 56, laser trimming and removing the protective film 56 are installed in the BSG apparatus. In such a manner, footprint of all the edge surface processing apparatus 1 can be decreased.

Further, the first embodiment describes that forming the protective film 56 (step S5), laser trimming (step S6) and removing the protective film 56 (step S7) are carried out in the same site X4, as example. However, it is not restricted the case mentioned above.

When sum of required time of the processes performed in the site X4 is longer than that in other sites X1-X3, X5, the process performed in the site X4 is rate-limiting processes, for example. The processes performed in the site X41-X5 are the forming of the protective film 56, the laser trimming and the removing of the protective film 56, the process performed in other sites X1-X3, X5 are replacement and re-movement of the wafer W to platform P1-P5 at the site X1, rough grinding at the site X2, fine grinding at the site X3 and CMP at the site X5, for example. In such case, the forming of the protective film 56, the laser-trimming and the removing of the protective film 56 can be performed at another site X1-X3, X5, for example. Specifically, new sites X1-X5 and new platforms P1-P5 are added in the edge surface processing apparatus 1 as shown in FIG. 1. A solution tube 14a is added at one site newly added between the site X3 and the site X4 and a pure water tube 14b is added at another site newly added between the site X4 and the site X5. The laser irradiation unit 13 can be leaved near the site X4. In such a manner, required time in each of the sites X1-X5 can be unified to totally improve the throughput.

On the other hand, when sum of required time of the processes performed in the site X4 is shorter than that in one of other sites X1-X3, X5, it is effective to perform in the same site X1-X5.

As another case, the forming of the protective film 56 (step S5), the laser trimming (step S6) and the removing the protective film 56 (step S7) to the wafer W can be performed at the site X3 in which fine grinding is performed. In such a manner, the site X4 is unnecessary so that a number of the platform P1-P5 set on the rotation table is also satisfied by four. In such a case, the laser irradiation unit 13, the solution tube 14a and the pure water tube 14b is set near the site X3. However, the optical pass 13b of the section laser irradiation unit 13, the solution tube 14a and the pure water tube 14b are movable. When the grind stone GR2 is contacted to perform fine grinding, the sites X1-X5, the optical pass 13b of the section laser irradiation unit 13, the solution tube 14a and the pure water tube 14b can be leaved. In this case, total throughput is not so decreased when required time of fine grinding is shorter than one of required time of the other processes. Especially, when sum of required time of the processes of fine grinding (step S4), the forming of the protective film 56, the laser trimming and the removing the protective film 56 is shorter than required time of one of other processes, waiting time after finishing fine grinding at the site X3 can be effectively used. Accordingly, the total throughput can be improved.

Furthermore, the forming of the protective film, the laser trimming and the removing of the protective film 56 can be performed after the CMP process. The CMP process and the cleaning using the cleaning unit 15 may not be performed. In such case, the CMP process and the cleaning are performed using another apparatus to the forming the protective film 56, the laser trimming and the removing the protective film 56.

In other words, a laser trimming apparatus performing the forming of the protective film 56, the laser trimming and the removing the protective film 56 is differently set up to the BSG apparatus performing rough grinding and fine grinding. Both apparatuses can be directly or indirectly connected through a connecting mechanism. As another case, one or two of forming unit of the protective film 56, a laser trimming unit and removing unit of the protective film 56 are installed in the BSG apparatus, others are differently set up to the BSG apparatus. Both apparatuses can be directly or indirectly connected through a connecting mechanism.

### Second Embodiment

Next, a second embodiment is described. A different point in the second embodiment as compared to the first embodiment is that laser trimming is performed between rough grinding and fine grinding. The protective film 56 is not formed not to be removed. Debris D generated in laser-trimming are removed in fine grinding.

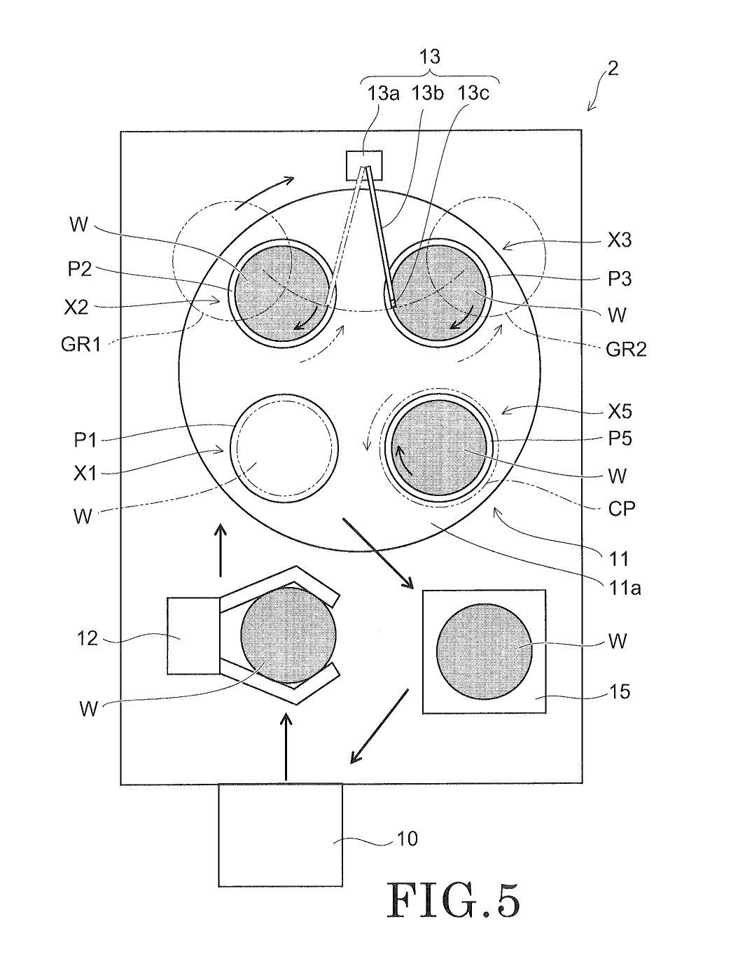

First, an edge surface processing apparatus according to the second embodiment is described. FIG. 5 is a plane view schematically showing an edge surface processing apparatus according to the second embodiment. As shown in FIG. 5, the site X4 which installed in FIG. 1 is not included in an edge surface processing apparatus 2 according to the second embodiment as compared to the edge surface processing apparatus 1 previously described in the first embodiment as shown in FIG. 1. In addition, four platforms P1-P4 are set up on a top plate 11a of a rotation stage 11. Further, a laser irradiation unit 13 is set up near the site X2, X3. In such a manner, an outlet portion 13c of the laser irradiation unit 13 can move on an orbit with an arc-shape between an outside edge of a wafer W positioned on the site X2 and an outside edge of a wafer positioned on the site X3. The solution tube 14a and the pure water tube 14b installed in the edge surface processing apparatus 1 as shown in FIG. 1 are not included in the edge surface processing apparatus 2 as shown in FIG. 5. A constitution of the edge surface processing apparatus 2 is the same as that of the edge surface processing apparatus 1 other than the portions described above.

Next, action of the edge surface processing apparatus constituted as described above according to the second embodiment, in other words, a method for processing an edge surface is explained.

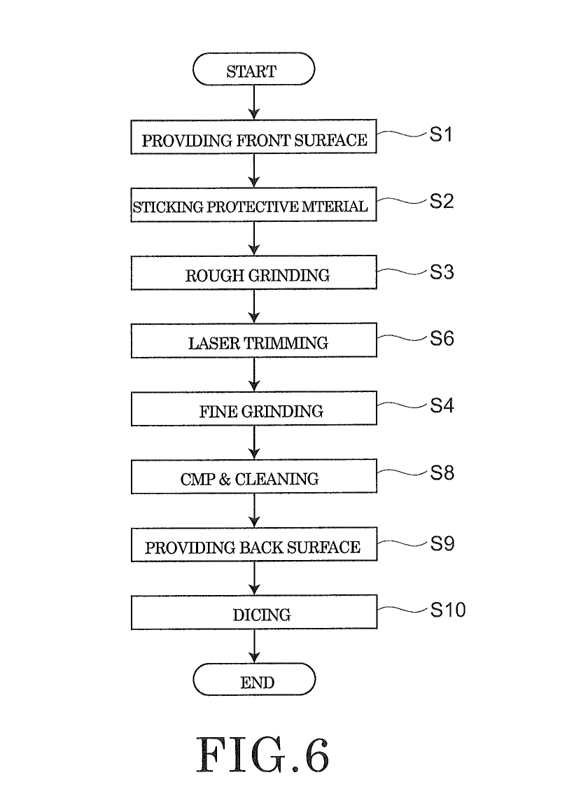

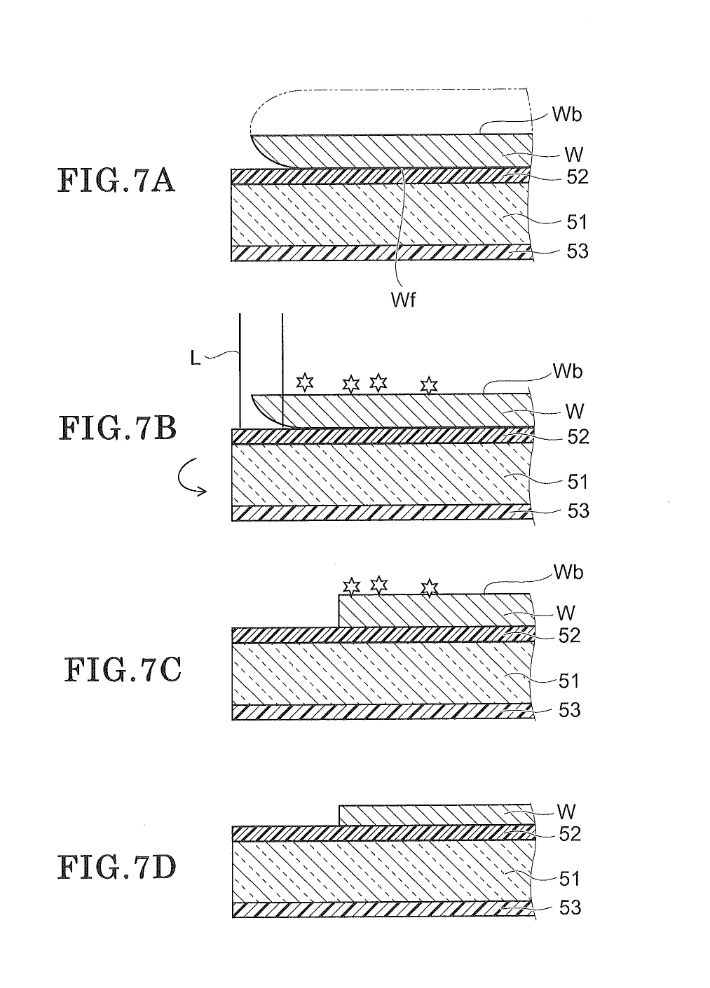

FIG. 6 is a flowchart showing a method for processing an edge surface according to the second embodiment. FIGS. 7A-7D are cross-sectional views showing the method for processing the edge surface according to the second embodiment.

As shown in FIG. 6, forming a surface structure at step S1, sticking a surface protection material at step S2 and fine grinding at step S3 are performed by using the same methods as described in the first embodiment. Rough grinding at S3 is performed at the site X2 in the edge surface processing apparatus 2 as shown in FIG. 5. In such a manner, a glass substrate 51 and BSG tape 53 are stuck on a surface W_{f} of the wafer W through an adhesive 52 and the wafer W with a portion of a back surface W_{b} is formed as shown in FIG. 7A. On the other hand, a thickness of the wafer W in this stage is thicker than a thickness of the wafer W after fine grinding as shown in FIG. 4A.

Processing steps after the steps mentioned above are different from the first embodiment. In other words, laser trimming is carried out as shown at S6 in FIG. 6 and FIG. 7B after rough grinding (step S3). The laser trimming can be performed at the site X2 or the site X3 after moving the platform P1 to the site X3. A method of laser trimming is the same as the method of first embodiment. On the other hand, a part of the debris D generated in laser trimming is attached on the back surface W_{b} of the wafer W as shown in FIGS. 7B, 7C, as the protective film 56 as shown in FIG. 4C is not formed in the second embodiment.

As shown at Step S4 in FIG. 6, fine grinding is performed at the site X3. In such a manner, the back surface W_{b} of the wafer W is further grinded so that the thickness of the wafer W is also thinned as shown at step S7 in FIG. 7D. Accordingly, the debris D attached on the back surface of the wafer W are removed with a portion of the back surface W_{b} of the wafer W.

Processing steps after the steps mentioned above are the same as the first embodiment. In other words, a CMP process is perform at the site 5, cleaning by pure water is performed in a cleaning unit 15 and the wafer W is leaved from the edge surface processing apparatus 2, as shown at step S8 in FIG. 6. As shown at steps S9, S10 in FIG. 6, a structure of the back surface W_{b} is performed on the back surface W_{b} of the wafer W and the wafer W is diced. In such a manner, semiconductor devices are fabricated. A method for processing edge surface other than the processes described above is the same as that of the first embodiment.

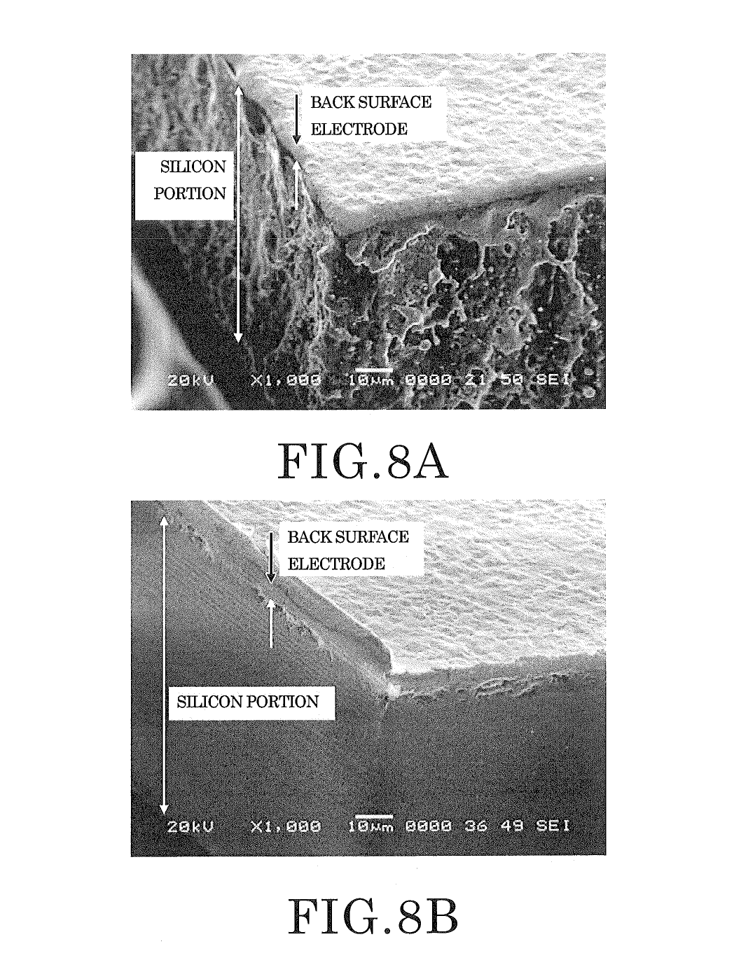

Next, morphology of the edge surface of the wafer W edge trimmed by such a manner is described. FIGS. 8A, 8B are SEM (scanning electron microscope) photographs showing processed surfaces of the wafer W. FIGS. 8A, 8B show processed surfaces processed by a laser abrasion method and a blade method, respectively. Back surface electrodes composed of metal are formed on the samples shown in FIGS. 8A, 8B, respectively. On the other hand, morphology of the processed surface of a portion of the silicon is the same in a case without the back surface electrode.

As shown in FIG. 8A, re-solidification structure can be recognized on the processed surface as the ablated silicon is solidified again on the processed surface in the case that the wafer W composed of silicon is processed by the laser abrasion method as the same as the first embodiment and the second embodiment. On the other hand, as shown in FIG. 8B, re-solidification structure cannot be recognized on the processed surface as the ablation and solidification of silicon is not occurred in a case that the wafer W composed of silicon is processed by the blade method.

Next, effects of the second embodiment are explained. Laser trimming (step S6) is performed between rough grinding (step S3) and fine grinding (step S4) according to the second embodiment as shown in FIG. 6. In such a manner, the debris D generated in laser-trimming can be removed by fine grinding. Therefore, forming and removing the protective film 56 are unnecessary to be able to simplify the total process.

In a case that a diameter of the wafer W is decreased from 200 to 199 mm, for example, a width tw of trimming is 500 μm which is equal to (200 mm-199 mm)/2. When a diameter of an irradiation area of laser light L is set to be 10 μm, rotations of at least 50 times (500/10 μm) are necessary for trimming the trimming width tw. When a linear speed of the wafer W is set to be 500 nn/sec, 1.256 sec, which is equal to 200×3.14/500 μm/sec, is necessary to rotate one time of the wafer W. Accordingly, 62.8 sec, which is equal to 1.256 (sec/one time×50 times) is necessary to rotate 50 times. In other words, about one minute is necessary. On the other hand, removing the protective film 56 is necessary for several minutes in a conventional case. Consequently, saving the removing of the protective film 56 can greatly shorten the total required time. Furthermore, the solution tube 14a and the pure water tube 14b are not necessary to install in the edge surface processing apparatus by saving the forming and removing of the protective film 56. Accordingly, the constitution of the edge surface processing apparatus 2 can be simplified.

Laser trimming is performed at the site X2 or the site X3 in the second embodiment. A number of the sites and a number of the platforms can be decreased from five to four, respectively, as compared to the edge surface processing apparatus 1 according to the first embodiment as shown in FIG. 1. Therefore, the constitution of the edge surface processing apparatus 2 can be simplified and an occupied area of the edge surface processing apparatus 2 can be also decreased.

On the other hand, laser trimming can be performed by forming the protective film 56 on the back surface W_{b} of the wafer W after fine grinding according to the first embodiment. In such a manner, as the thickness of the wafer W can be thinned when laser-trimming is performed. Accordingly, amount of silicon removed by laser trimming can be decreased. Consequently, efficiency of laser trimming can be improved.

Furthermore, decrease of the throughput due to laser trimming can be suppressed as the site performed laser trimming can be selected from the site X2 and the site X3. When the required time of rough grinding performed at the site X2 is shorter than that of fine grinding performed at the site X3, for example, laser trimming can be performed at the site X2. On the other hand, when the required time of fine grinding is shorter than that of rough grinding, for example, laser-trimming can be performed at the site X3. In such a manner, waiting time after finished the process which has relatively shorter required time can be effectively used. Effects other than the required time described above in the second embodiment are the same as those in the first embodiment.

A method for processing edge surface and an edge surface processing apparatus, where the plate member and the surface protection material do not sandwich the debris D and the plate member can be easily controlled.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for processing an edge surface, comprising:
grinding a second surface of a wafer, the second surface opposite to a first surface of the wafer being stuck with a surface protection material;
forming a protective film on the first surface;
irradiating a portion including an outside edge of the wafer with laser light to remove the portion including the outside edge in a state that the wafer is rotating and an irradiation position of the laser light is approaching to a rotation axis of the wafer, an absorption ratio of the wafer to the laser light being higher than an absorption ratio of the surface protection material to the laser light; and
removing the protective film.

2. The method of claim 1, wherein
a wavelength of the laser light is ranged between 300 nm-2,000 nm.

3. The method of claim 1, wherein
the irradiation position of the laser light moves in synchronization with a rotation of the wafer.

4. The method of claim 1, wherein
a first grinding and a second grinding after the first grinding are included in the grinding.

5. The method of claim 4, wherein
a first grinding surface used in the first grinding is rougher than a second grinding surface used in the second grinding.

6. A method for processing an edge surface, comprising:
irradiating a portion including an outside edge of a plate member with laser light to remove the portion including the outside edge, a first surface of the plate member being stuck with a surface protection material, an absorption ratio of the plate member to the laser light being higher than an absorption ratio of the surface protection material to the laser light.

7. The method for claim 5, further comprising:
grinding a second surface opposite to the first surface of the plate member after the irradiating.

8. The method for claim 5, wherein
the plate member is a wafer and the irradiating is performed in a state that the wafer is rotating and an irradiation position of the laser light is approaching to a rotation axis of the wafer.

9. The method of claim 8, wherein
the irradiation position of the laser light moves in synchronization with a rotation of the wafer.

10. The method of claim 5, wherein
a wavelength of the laser light is ranged between 300 nm-2,000 nm.

11. The method of claim 6, further comprising:
grinding the second surface of the plate member before the irradiating.

12. The method of claim 11, wherein
a second grinding surface used in the grinding of the second surface is rougher than a first grinding surface used in the grinding of the first surface.

13. An edge surface processing apparatus, comprising:
an laser irradiation unit configured to irradiate a portion including an outside edge of a plate member with a laser light, a surface protection material being stuck on a first surface of the plate member, an absorption ratio of the plate member to the laser light being higher than an absorption ratio of the surface protection material to the laser light; and
an alignment unit configured to relatively move an irradiation position of the laser light along an outside edge.

14. The apparatus of claim 13, wherein
the plate member is a wafer and the alignment unit includes a plurality of rotation sections configured to rotate the wafer, and a moving section configured to move an irradiation position of the laser light to a radial direction of the wafer.

15. The apparatus of claim 14, wherein
the irradiation position of the laser light is approached to a rotation axis of the wafer by the moving section, in a state that the wafer is rotating by each of the rotation section.

16. The apparatus of claim 14, wherein
the moving section is configured to move in synchronization with a rotation of the rotation section to decide the irradiation position of the laser light.

17. The apparatus of claim 13, wherein
a wavelength of the laser light is ranged between 300 nm-2,000 nm.

18. The apparatus of claim 13, further comprising:
a first grinding unit and a second grinding unit set up an upper side of the rotation unit, the first grinding unit and the second grinding unit grinding the plate member, a first grinding surface used in the first grinding unit being rougher than a second grinding surface used in the second grinding unit.

19. The apparatus of claim 13, further comprising:
a discharge unit set up at an upper side of the rotation unit and configured to provide a first liquid to form the surface protection material and a second liquid to remove the surface protection material to the plate member.

20. The apparatus of claim 13, further comprising:
a rotation stage, the rotation unit being provided on a first surface of the rotation stage and configured to be rotated round by the rotation stage.
